(19) United States
(12) Patent Application Publication
(10) Pub. No.: US 2011/0200790 A1
(43) Pub. Date: Aug. 18, 2011

(54) Method for Localised Electro-Grafting on Conducting or Semiconducting Substrates in the Presence of a Microelectrode

(75) Inventors: Julienne Charlier, Gif- Sur- Yvette (FR); Serge Palacin, Montigny le Bretonneux (FR); Achraf Ghorbal, Gif Sur Yvette (FR); Federico Grisotto, Paris (FR)

(73) Assignee: COMMISSARIAT A L'ENERGIE ATOMIQUE ET AUX ENERGIES ALTERNATIVES, Paris (FR)

(21) Appl. No.: 12/934,724

(22) PCT Filed: Mar. 26, 2009
(86) PCT No.: PCT/EP2009/053608

§ 371 Date: May 4, 2011

(30) Foreign Application Priority Data
Mar. 28, 2008 (FR) 0852055

(51) Int. Cl. B32B 3/00; H01L 21/312; H01L 51/00; B05D 5/12

(52) U.S. Cl. 428/172; 438/780; 257/40; 427/125; 257/E51.001; 257/E21.259

(57) ABSTRACT

The present invention concerns a method for localized grafting of an organic film in a selected area of an electrically conducting or semiconducting substrate, in the presence of a liquid solution containing at least one organic adhesion primer and at least one radically polymerizable monomer, different from the organic adhesion primer, by applying an electric potential to the substrate in the presence of a polarized microelectrode. The present invention also concerns an insulating organic film grafted on a conducting or semiconducting substrate, capable of being prepared using said method.

### Technical Field

The present invention concerns the field of organic surface coatings, said coatings assuming the form of organic films.

It more particularly concerns a method for preparing such organic coatings in the presence of a microelectrode and using solutions suitably selected so as to allow the simple and reproducible formation of organic films by selective coating on electrically conducting or semiconducting surfaces and in particular by electro-grafting.

### BACKGROUND OF THE INVENTION

To date, several techniques exist allowing the production of thin organic films on substrates, all generally based on an adapted family or class of molecules.

The method of forming a coating by centrifugation, or “spin coating,” does not require a particular affinity between the deposited molecules and the substrate of interest, which is also the case for related techniques of forming coatings by submersion (“dip coating”) or spraying (“spray coating”). Indeed, the cohesion of the deposited film rests essentially on the interactions between the components of the film, which can, for example, be cross-linked after deposition to improve the stability thereof. These techniques are very versatile, applicable to any type of surface to be covered, and very reproducible. However, they do not allow any effective grafting between the film and the substrate (it involves simple physisorption). The thicknesses produced are difficult to control, especially for the finest depositions (less than 20 nanometers), and are rarely uniform over the entire surface.

Other techniques for forming an organic coating on the surface of support, such as plasma deposition or photochemical activation, rest on a same principle: generating, near the surface to be covered, unstable forms of a precursor, which evolve while forming a film on the substrate. Although plasma deposition does not require any particular property of these precursors, the photo-activation requires the use of photosensitive precursors, the structure of which evolves under light irradiation. These techniques generally give rise to the formation of adhesive films, although it is most often impossible to discern whether that adhesion is due to a cross-linking of a film topologically closed around the object or a real formation of bonds at the interface.

Self Assembled Monolayers (SAM) are a very simple technique to carry out that does, however, require the use of generally molecular precursors having a sufficient affinity for the surface of interest to be coated. We then talk about precursor-surface couples, such as sulfurated compounds having an affinity for gold or silver, trihalogenosilanes for oxides such as silica or aluminum, polyaromatics for graphite or carbon nanotubes. In all cases, the formation of the film rests on a specific chemical reaction between part of the molecular precursor (the sulfur atom in the case of thiols, for example) and certain “receiver” sites of the surface. A chemisorption reaction ensures the adhesion. However, although couples involving oxide surfaces can give rise to the formation of very solidly grafted films (the Si—O bond involved in the chemisorption of trihalogenosilanes on silica is among the most stable in chemistry), there is nothing of the sort when we look at metals or semiconductors without oxide.

Anodic electropolymerization consists of polymerizing monomeric species in the presence of electrons near an electrically conducting or semiconducting surface. The polymerization leads to the formation of a film by precipitation in the vicinity of the surface. However, no bond of a covalent nature is created between the surface and the polymer, with the result that the films obtained do not have optimal resistance to attacks. We can cite pyrrole in particular among the monomers that can be used according to this technique.

Organic coatings are abundantly used in various technical fields such as electronics or biology. Considering recent developments in those sectors, it is becoming essential today to master coating methods on micrometric and nanometric scales, i.e. to be able to localize these coatings as finely as possible while controlling the positions, gaps and stability of the modified zones. None of the different surface modification methods listed above provide access to localized and robust grafting of non-conducting organic films.

Scanning electrochemical microscopy is a technique that, after two decades of development, is today based on broad theoretical knowledge as well as a significant number of experimental applications. The use of this technique has made it possible to produce organic and inorganic patterns on different substrates with a micrometric resolution.

Zhou and coll. [J. Electrochem. Soc., 1997, 144, 4, 1202-1207] prepared micrometric polyaniline (PANI) patterns on platinum, gold, and carbon surfaces through local modification of the pH using a scanning electrochemical microscope (SECM). Increasing the pH makes it possible to modify the electrochemical potential of the aniline and thus leads to a deposition of the polyaniline. Performing the deposition with a micrometric to nanometric resolution currently seems very difficult. Indeed, the authors noted that the formation of H₂ within the reaction medium was a handicap.

Mark and coll. [Chem. Mater., 2001, 13, 747-752] confirmed the possibility of depositing conducting polymers by applying the scanning electrochemical microscopy technique to polythiophene (PT). The authors also specify that such polymers have great latitude in their applications due to the modularity of their conductivity and concomitant variations in their optical properties. They thus showed that it was possible to deposit a film of PT from thiophene by oxidation in an acid medium on a manganese dioxide surface. The reaction seems to lead to the formation of oligomers not exceeding octamer size. At best, the polymers formed correspond to chains of 20 to 30 units. Moreover, the method causes an electropolymerization near the electrode that results in affecting the uniformity of the applied potential.

Depositing polypyrrole (Ppy) films has also been reported in the literature. Here again, it seems that the technique used leads to a simple deposition on the surface, and that, depending on the environmental conditions, the film formed is particularly metastable [Langmuir, 2004, 20, 9236-9241] and sensitive.

It appears that the existing methods for localizing the chemical grafting of electropolymers only make it possible, to date, to access conducting polymer films. Moreover, it is notable that their stability remains precarious.

Few techniques for localized electro-grafting of insulating films have been developed. In this respect, we can cite in particular international application WO 02/070148, which concerns heterogeneous substrates whereof the components have different work functions. In that application, described in particular is a localized grafting method, without mask, of organic molecules capable of being electrically activated, on a composite surface comprising electrically conducting and/or semiconducting portions, by putting said organic molecules in contact with said composite surface. In that method, the grafting is done electrochemically in a single step on chosen, defined zones of said conducting and/or semiconducting portions. Said zones are brought to a potential greater than or equal to a threshold electrical potential determined in relation to a reference electrode, said threshold electrical potential being the potential beyond which the grafting of said organic molecules occurs. The selectivity rests on the properties that are given to the materials making up the different portions of the surface. Under these conditions it is often crucial to have the selected zones undergo a specific treatment.

It appears that today the techniques for localized electro-grafting of insulating films are not easy to implement because they require either prior treatment of the supports, or the use of masks. There is therefore a need, unmet to date, to provide a method allowing simple access to insulating, stable films solidly bound to the surfaces in the form of micro and nanostructured patterns.

### BRIEF DESCRIPTION OF THE INVENTION

The present invention makes it possible to resolve the drawbacks of the method and coatings of the prior art.

The present invention concerns a method for preparing an organic film in a selected area of an electrically conducting or semiconducting substrate, in the presence of a liquid solution containing at least one organic adhesion primer and at least one radically polymerizable monomer and different from the organic adhesion primer, by applying an electric potential to the substrate in the presence of a polarized microelectrode. The grafting is done selectively on at least one portion of the surface using said microelectrode.

The invention more particularly concerns a method for preparing an organic film in a selected area of an electrically conducting or semiconducting substrate, comprising the following steps:

a) positioning a microelectrode near the surface of the selected area;

b) putting a liquid solution comprising at least one organic adhesion primer and at least one radically polymerizable monomer, different from said adhesion primer, in contact with at least said selected area;

c) polarizing said microelectrode and the surface of said substrate, the electric potential of the surface being more cathodic than the reduction potential of the organic adhesion primer used in step (b).

In general, the sequence of steps is either (a), (b) and (c), or (a), (c) and (b).

In the context of the present invention, “semiconductor” refers to an organic or inorganic material having an intermediate electrical conductivity between metals and insulators. The conductivity properties of a semiconductor are influenced primarily by the current carriers (electrons or holes) presented by the semiconductor. These properties are determined by two particular energy bands, called valence band (corresponding to the electrons involved in the covalent bonds) and the conduction band (corresponding to the electrons in an excited state and capable of moving in the semiconductor). The “gap” represents the energy difference between the valence band and the conduction band. A semiconductor also corresponds, unlike insulators or metals, to a material whereof the electric conductivity can be controlled, in large part, by adding doping agents that correspond to foreign elements inserted into the crystalline structure of the semiconductor.

The substrate used in the context of the method according to the invention can have any surface whatsoever typically used in electro-grafting and advantageously an inorganic surface. Such an inorganic surface can in particular be chosen among conducting materials such as metals, noble metals, corroding metals, transition metals, metal alloys, and for example Ni, Zn, Au, Ag, Cu, Pt, Ti and steel. The inorganic surface can also be chosen among semiconducting materials such as Si, SiC, AsGa, Ga, etc. . . .

Thus, said inorganic surface of the substrate used in the method according to the invention is generally made up of a material chosen among metals, noble metals, corroding metals, transition metals, metal alloys and semiconducting materials.

Within the meaning of the invention, a “microelectrode” (ME) corresponds to an electrode whereof at least one of the characteristic dimensions (the diameter for a disc) is at most in the vicinity of a few tens of micrometers. More generally, all of the dimensions of a ME are at most in the vicinity of a few tens of micrometers. Within MEs, we distinguish “ultramicroelectrodes” (UME), whereof one of the characteristic dimensions (diameter for a disc) is at most in the vicinity of a few tens of nanometers. Generally at least two of the dimensions of a UME are at most in the vicinity of a few tens of nanometers.

In MEs, the current measured over long periods is stationary or practically stationary (logarithmic decrease). The ohmic drop is negligible when such electrodes are used. Thus, it is not necessary to use a reference electrode as typically done in electrochemistry.

By way of microelectrode usable in the context of the present invention, it is possible to use the probe of a scanning tunneling microscope (STM) and advantageously that of a scanning electrochemical microscope (SECM) or an electrochemical atomic force microscope (el-AFM). Advantageously, a ME will be used, corresponding to the probe of a microscope, whereof the diameter is less than 200 μm, or even less than 10 μm.

As a result, the microelectrode used in the method according to the present invention is advantageously chosen from the group made up of an ultramicroelectrode (UME), the probe of a tunneling microscope (STM), the probe of a scanning electrochemical microscope (SECM) or the probe of an electrochemical atomic force microscope (el-AFM).

The positioning of the microelectrode during step (a) of the method according to the present invention is generally done by placing the ME at the vertical of the surface of the selected area. The ME is placed at a distance from the substrate determined, according to the method usually used in electrochemical microscopy, using an electrochemical mediator corresponding to a known oxidizing/reducing couple such as the Fe³⁺/Fe²⁺ system. A curve, called the “approach curve,” corresponding to the value of the current of the mediator at the ME as a function of the distance between the ME and the substrate, is first done. The working distance (i.e. the distance between the ME and the surface of the support) chosen to carry out the method is that for which the ratio between the value of the intensity of the current measured at the working distance and that of the current measured to infinity, i.e. far from the surface, is between 1.2 and 2.5. In general, such a value corresponds to a distance such that the ratio between the working distance and the radius of the ME is between 0.2 and 2. Generally for a ME whereof the diameter is between 20 and 150 μm, the working distance will be between 15 and 25 μm and typically around 20 μm.

The term “organic adhesion primer” corresponds, in the context of the present invention, to any organic molecule capable, under certain conditions, of chemisorbing to the surface of a solid support by radical reaction, and in particular by electro-grafting, and including a reactive function with regard to another radical after chemisorption.

The organic adhesion primer is advantageously a cleavable aryl salt chosen from the group made up of aryl diazonium salts, aryl ammonium salts, aryl phosphonium salts, aryl iodonium salts, and aryl sulfonium salts. In these salts, the aryl group is an aryl group that can be represented by R as defined below.

The organic adhesion primers, and particular the cleavable aryl salts, can in particular include compounds of the following formula (I):

R—N₂⁺,A⁻ (I)

in which:
A represents a monovalent anion, and
R represents an aryl group.

By way of the aryl group of the cleavable aryl salts, and in particular of the compounds of formula (I) above, we can advantageously cite aromatic or heteroaromatic carbonaceous structures, possibly mono- or polysubstituted, made up of one or several aromatic or heteroaromatic cycles each including 3 to 8 atoms, the heteroatom(s) being able to be N, O, P or S. The substituents can contain one or several heteroatoms, such as N, O, F, Cl, P, Si, Br or S as well as C1 to C6 alkyl groups in particular.

Within the cleavable aryl salts and in particular compounds of formula (I) above, R is preferably chosen among the substituted aryl groups by electron attracting groups such as NO₂, COH, ketones, CN, CO₂H, NH₂, esters and halogens. Particularly preferred aryl-type groups R are nitrophenyl and phenyl radicals.

Within the compounds of formula (I) above, A can in particular be chosen among the inorganic anions such as halides like I⁻, Br⁻ and Cl⁻, halogenoborates such as tetrafluoroborate, perchlorates and sulfonates and organic anions such as alcoholates and carboxylates.

By way of organic adhesion primers and, more particularly, compounds of formula (I), it is particularly advantageous to use a compound chosen from the group made up of phenyldiazonium tetrafluoroborate, 4-nitrophenyldiazonium tetrafluoroborate, 4-bromophenyldiazonium tetrafluoroborate, 4-aminophenyldiazonium chloride, 2-methyl-4-chlorophenyldiazonium chloride, 4-benzoylbenzenediazonium tetrafluoroborate, 4-cyanophenyldiazonium tetrafluoroborate, 4-carboxyphenyldiazonium tetrafluoroborate, 4-acetamidophenyldiazonium tetrafluoroborate, 4-phenylacetic diazonium acid tetrafluoroborate, 2-methyl-4-[(2-methylphenyl)diazenyl]benzenediazonium sulfate, 9,10-dioxo-9,10-dihydro-1-anthracenediazonium chloride, 4-nitronaphtalenediazonium tetrafluoroborate and naphtalenediazonium tetrafluoroborate.

The concentration of adhesion primer in the liquid solution is variable and depends on the experimenter's wishes. It is, however, recommended to work at a concentration for which the primer is completely soluble in the liquid solution. Thus, for example, for aryl diazonium salts, the concentration will typically be between 10⁻³ and 5.10⁻² M.

Advantageously, in the case where the adhesion primer is an aryl diazonium salt, the pH of the solution is less than 7, typically less than or equal to 3. It is recommended to work at a pH between 0 and 3. If necessary, the pH of the solution can be adjusted to the desired value using one or several acidifying agents well known well known by those skilled in the art, for example using inorganic or organic acids such as hydrochloric acid or sulfuric acid.

The adhesion primer is generally introduced as is into the liquid solution as previously defined. Thus, in one particular embodiment, the method according to the present invention includes a step for preparing the adhesion primer, in particular when it is an aryl diazonium salt. Such compounds are generally prepared from arylamine, able to include several amine substituents, by reaction with NaNO₂ in acid medium. For a detailed description of experimental forms usable for such a preparation in situ, those skilled in the art may refer to the open literature [D. Belanger et al. (2006) Chem. Mater. Vol. 18; 4755-4763]. Preferably, the grafting will then be done directly in the preparation solution of the aryl diazonium salt.

The radically polymerizable monomers used in the context of the present invention correspond to the monomers capable of radically polymerizing after priming with a radical chemical entity. Typically, this involves molecules including at least one ethylene-type bond. Vinyl monomers, in particular the monomers described in patent application FR 05 02516 as well as patent FR 03 11491, are particularly concerned.

According to one particularly advantageous embodiment of the invention, the radically polymerizable monomer(s) and in particular the vinyl monomer(s) are chosen among monomers of the following formula (II):

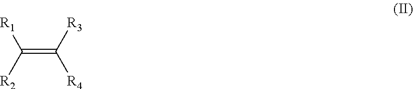

in which groups R₁ to R₄, identical or different, represent a non-metal monovalent atom such as a halogen atom, a hydrogen atom, a saturated or unsaturated chemical group, such as an alkyl group, an aryl group, a —COOR₅ or —OC(O)R₅ group in which R₅ represents a hydrogen atom or a C₁-C₁₂ alkyl group and preferably C₁-C₆, a nitrile, a carbonyl, an amine or an amide.

The radically polymerizable monomers and in particular the compounds of formula (II) above are in particular chosen among the group formed by vinyl esters such as vinyl acetate, acrylic acid, acrylonitrile, methacrylonitrile, methyl methacrylate, ethyl methacrylate, butyl methacrylate, propyl methacrylate, hydroxyethyl methacrylate, hydroxypropyl methacrylate, glycidyle methacrylate and their derivatives; acrylamides and in particular aminoethyl, propyl, butyl, pentyl and hexyl methacrylamides, cyanoacrylates, diacrylates and dimethacrylates, tri-acrylates and tri-methacrylates, tetra-acrylates and tetra-methacrylates (such as pentaerythritol tetramethacrylate), styrene and its derivatives, parachloro-styrene, pentafluoro-styrene, N-vinyl pyrrolidone, 4-vinyl pyridine, 2-vinyl pyridine, vinyl, acryloyl or methacryloyle halides, di-vinylbenzene (DVB), and more generally vinyl or acrylate-, methacrylate-based cross-linking agents, and their derivatives.

According to one specific embodiment, the monomers used are those that, unlike compounds soluble in any proportion in the considered liquid solution, are soluble up to a certain proportion in the solution, i.e. the value of their solubility in that solution is finite. The monomers that can be used according to the method of the invention can thus be chosen among the compounds whereof the solubility in the liquid solution is finite and more particularly less than 0.1 M, more preferably between 5.10⁻² and 10⁻⁶ M. Such monomers for example include butyl methacrylate, the solubility of which, measured under normal temperature and pressure conditions, is about 4.10⁻² M. According to the invention, and unless otherwise indicated, the normal pressure and temperature conditions (NPTC) correspond to a temperature of 25° C. and a pressure of 1.10⁵ Pa

The invention is also applicable to a mixture of two, three, four, or more different monomers chosen among the monomers previously described.

The quantity of radically polymerizable monomers in the liquid solution can vary depending on the experimenter's wishes. This quantity can be greater than the solution of the considered monomer in the liquid solution used and can for example represent 18 to 40 times the solubility of said monomer in the liquid solution at a given temperature, generally the ambient temperature or reaction temperature. Under these conditions, it is advantageous to use means allowing the dispersion of the monomer molecules in the liquid solution such as an ultrasound treatment.

In the context of the invention, an organic film corresponds to any film of an organic nature, from several units of organic chemical species, covalently bound to the surface of the support on which the method according to the invention is implemented. They are particularly films covalently bound to the surface of a support and comprising at least one layer of structural units of a similar nature.

The liquid solution containing, in additional to the adhesion primer, at least one radically polymerizable monomer different from the adhesion primer, the organic film obtained according to the method of the invention can be polymer or copolymer, from several monomeric units of identical or different chemical species and/or adhesion primer molecules. The films obtained using the method according to the present invention are “essentially” of the polymer type inasmuch as the film also incorporates species from the adhesion primer and not just from the monomers present. Advantageously, the organic film in the context of the invention has a sequence of monomeric units in which the first unit is formed by a derivative of the first adhesion primer, the other units being indifferently derived from the adhesion primers and the polymerizable monomers.

Depending on the thickness of the film, its cohesion is ensured by the covalent bonds that develop between the different units. In particular, the invention deals with insulating organic films and, more specifically, insulating polymer films. Inasmuch as the conductivity of the organic films is based on the electronic conjugation, which results in optical transitions with a small gap, an organic film will typically be considered insulating if the value of the attenuation coefficient k measured by electrochemical impedance ellipsometry is between 0 and 0.05.

The liquid solution, comprising at least one adhesion primer and at least one radically polymerizable monomer, implemented in the context of the present invention can also contain a solvent. It is preferable for the solvent used to be a protic solvent. “Protic solvent” refers, in the present invention, to a solvent including at least one hydrogen atom capable of being released in proton form under non-extreme conditions.

The protic solvent is advantageously chosen from the group made up of water, acetic acid, hydroxylated solvents such as methanol and ethanol, liquid glycols with a low molecular weight such as ethyleneglycol, and mixtures thereof. According to one specific embodiment of the invention, a pure protic solvent can be used in a mixture with an aprotic solvent with the understanding that the resulting mixture has the characteristics of a protic solvent and will thus be considered as such.

The liquid solution, comprising an adhesion primer and a radically polymerizable monomer, implemented in the context of the present invention can also contain at least one supporting electrolyte. Said supporting electrolyte can in particular be chosen among the salts of quaternary ammoniums such as perchlorates, tosylates, tetrafluoroborates, hexafluorophosphates, the halides of short-chain quaternary ammoniums, sodium nitrate and sodium chloride.

These salts of quaternary ammoniums include in particular, for example, tetraethylammonium perchlorate (TEAP), tetrabutylammonium perchlorate (TBAP), tetrapropylammonium perchlorate (TPAP), benzyltrimethylammonium perchlorate (BTMAP).

The liquid solution, comprising an adhesion primer and a radically polymerizable monomer, implemented in the context of the present invention, can also contain at least one surface active agent, in particular to improve the solubility of the radically polymerizable monomer. A precise description of the surface active agents that can be used in the context of the invention is provided in patent application FR 2 897 876, to which those skilled in the art may refer. A single surface active agent or a mixture of several surface active agents can be used.

According to the invention, it is preferable for the electric potential used in step (c) of the method according to the present invention to be close to the reduction potential of the adhesion primer used and that reacts on the surface. Thus the value of the electric potential applied can be up to 50% higher than the reduction potential of the adhesion primer, more typically it will not be greater than 30%.

The polarization of the microelectrode and the surface of said substrate can be done using any technique known by those skilled in the art, and particularly under linear or cyclic voltamperometry conditions, under potentiostatic, potentiodynamic, intensiostatic, galvanostatic, galvanodynamic conditions or by simple or pulsed chronoamperometry. Advantageously, the method according to the present invention is done under static or pulsed chronoamperometry conditions. In static mode, the electrode is polarized for a duration generally shorter than 5 seconds, more generally lasting 2 seconds. In pulsed mode, the number of pulses will preferably be between 1 and 10 and, even more preferably, between 1 and 5, their duration generally being from 50 to 150 ms, typically 100 ms.

The method according to the present invention can thus in particular be carried out in an electrolytic cell including different electrodes: a first working electrode forming the surface intended to receive the film, an auxiliary electrode corresponding to the ME, as well as, possibly, a reference electrode.

The microelectrode can have different shapes, and can in particular correspond to a disc, a sphere, a hemisphere, a micropipette, an interdigital comb, a cone, a ring, concentric rings or a strip. Its shape can thus correspond to any pattern whatsoever and be homothetic to the contours of the selected area.

According to one particular arrangement, several microelectrodes can be used simultaneously on a same substrate.

According to one specific embodiment, the method includes an additional step for moving the microelectrode near the selected area. Advantageously, this additional step (d) is carried out after the sequence of steps (a), (b) and (c) or (a), (c) and (b). This step is useful when the selected area has a substantially larger surface than that of the surface of the ME. According to this form, it is thus possible to establish, on the surface of the substrate, selected areas corresponding to complex and vast patterns in light of the size of the ME.

This aim can also be achieved by using several microelectrodes positioned near the surface of a conducting or semiconducting substrate on which the organic film must be prepared. The distance between the microelectrodes will be chosen as a function of the complex patterns to be obtained. Simultaneously using several microelectrodes during implementation of the method makes it possible to quickly produce complex patterns on a same surface. Identical or different liquid solutions can be used in this alternative. Advantageously a single liquid solution is used.

According to another embodiment, the method includes an additional step (e) of functionalizing the organic film thus prepared. The functionalization is done from organic functions present on the surface of the organic film prepared according to the method of the present invention. Regarding the functionalization of organic films, see in particular international application WO 2004/005410.

The invention also concerns the use of microscope, such as an electrochemical microscope, or a microelectrode, to graft an organic film, typically insulating, on a selected area of an electrically conducting or semiconducting substrate. The invention also consists of the simultaneous use of several microelectrodes to graft several organic films, typically insulating, on a set of selected areas of an electrically conducting or semiconducting substrate.

The organic films obtained using the method according to the invention do not have a uniform thickness. The thickness of these organic films has a characteristic profile with three characteristic areas called “inner area,” “hollow area,” and “outer area.” This characteristic profile makes it possible to distinguish the films obtained using the method according to the present invention from the organic films obtained using the methods of the prior art. The invention also concerns an insulating organic film grafted on a conducting or semiconducting substrate, capable of being prepared using a method as previously defined, the thickness of said film having at least one inner area with a maximum height h(i) and an outer area with a maximum height h(e), with h(i)<h(e), separated by a hollow area with a maximum height h(c) with h(c)<h(i). As an example, the height ratios between the different areas may have the following values: h(i)/h(e)=0.5 and h(c)/h(i)=0.8. Typically, the respective diameters of the inner area and the outer area corresponds to about two and three times that of the ME used to form them.

Using microelectrodes makes it possible to carry out reactions in limited volumes, also with mediums very concentrated in reactive species but also without electrolyte support.

The described method makes it possible to produce very complex organic patterns on many surfaces. Implementing the method on a same surface to form organic films of different natures also makes it possible to access coatings that can be functionalized selectively in relation to the chemical functions present.

The invention will be well understood in light of the following examples that serve solely as illustrations and must in no way be understood as limiting the scope thereof.

### BRIEF DESCRIPTION OF THE DRAWINGS

FIG. 1 diagrammatically illustrates the formation of patterns in dot (a) or line (b) form on the surface of a substrate using a primer, a diazonium salt (ArN₂), and a monomer, here acrylic acid (AAc).

FIG. 2 corresponds to an image of a grafted surface obtained by optical microscopy after grafting by static chronoamperometry as a function of the diameter of the ME: 25 μm (FIG. 2a), 50 μm (FIG. 2b) and 100 μm (FIG. 2c).

FIG. 3 corresponds to a histogram illustrating the ratio existing between the size of the grafted surface, for different areas, by static chronoamperometry and the diameter of the ME.

FIG. 4 corresponds to infrared spectrums obtained after treatment on different parts of the surface: outside the grafting area (FIG. 4a), in the inner area after rinsing and exposure to ultrasounds (FIG. 4b), and in the inner area before rinsing (FIG. 4c).

FIG. 5 corresponds to an image of a grafted surface obtained by optical microscopy after grafting by chronoamperometry in dynamic mode, the ME being in motion.

FIG. 6 shows images of a grafted surface obtained by optical microscopy after grafting by chronoamperometry for different heights of a ME with a diameter of 100 μm (FIG. 6a) and a ME with a diameter of 25 μm (FIG. 6b).

FIG. 7 corresponds to an image of a grafted surface obtained by optical microscopy after grafting by chronoamperometry of two different vinyl monomers with a ME with a diameter of 10 μm.

### DETAILED DESCRIPTION OF SPECIFIC EMBODIMENTS

The experiments described below were conducted using a plate ME having a disc shape, which was prepared according to a standard protocol.

In order to make an electrode, the end of a glass capillary (borosilicate) was first sealed such that it assumes a conical shape, then, a straight platinum wire (99.9% pure, Goodfellow, United Kingdom) with a diameter of 100, 50, 25, or 10 μm was introduced into the capillary and the second end of the capillary was then sealed above.

The “sealed” wire was then connected to a thicker wire using a soft solder. The device was then polished with sandpaper of increasing roughness (grit size of 600 then 1200, or an average diameter of 15 μm and 5 μm, respectively), such that the value of the ratio (RG) of the total radius of the ME (glass+wire) over the radius of the metal surface is less than 10 (typically 2.6<RG<7.6) and the metal surface is smooth.

Before the MEs were used, they were washed in ultra-pure water (Milli-Q) and exposed to ultrasounds. The quality of the MEs was tested using the system (Fe(CN)₆³⁻/Fe(CN)₆⁴⁻) because it has a rapid electron transfer. The MEs were considered to have a satisfactory quality when a voltammogram in the stationary state, made for a potential varying from 0.25 V (in reference to an Ag electrode) to 0.4 V, having a current sensitivity of 100 nA, was superimposable on that obtained for an identical potential variation in the opposite direction.

The experiments were conducted in a Teflon electrochemical cell using a scanning electrochemical microscope SECM370 (Uniscan Instrument). The movements of the microscope probe, and by extension of the ME, were done using a computer-controlled device allowing remarkable precision on the micrometric scale. The value of the potential and its adjustment as well as the measurements of the current were done by a potentiostat/galvanostat integrated into the microscope.

The approach curve on the z axis, i.e. the distance between the probe and the surface of the sample, and the flatness along the X-Y axis of the sample surface, were adjusted from the potential value corresponding to the reduction tray of an aqueous solution of Fe(CN)₆³⁻(5.10⁻³ M, KCl 0.1 M). The solution allowing the adjustment was then evacuated and the entire device was rinsed with ultra-pure water.

The electro-grafting was done using a standard system with three electrodes: the working electrode being formed by a glass slide (Pyrex®) covered with 2 nm of chrome and 100 nm of gold (99.9% pure), vacuum deposited, the reference electrode being made up of a silver wire (diameter 1 mm) and the ME used corresponding to the auxiliary electrode of the system. The positioning of the ME in relation to the surface of the sample was done by studying the reduction current at the electrode for the adjusting solution as a function of the distance d to the surface of the sample, i.e. the working electrode. The results described below were obtained for a distance set at 20 μm.

Unless otherwise specified, the electrolytic solution corresponded to 300 μl of a mixture of an aqueous solution of commercial acrylic acid (0.7 M), 4-nitrobenzenediazonium tetrafluoroborate (2.10⁻³ M) in an aqueous solution of H₂SO₄ (0.25 M, analytical quality), for an exposed sample surface of 0.2 cm².

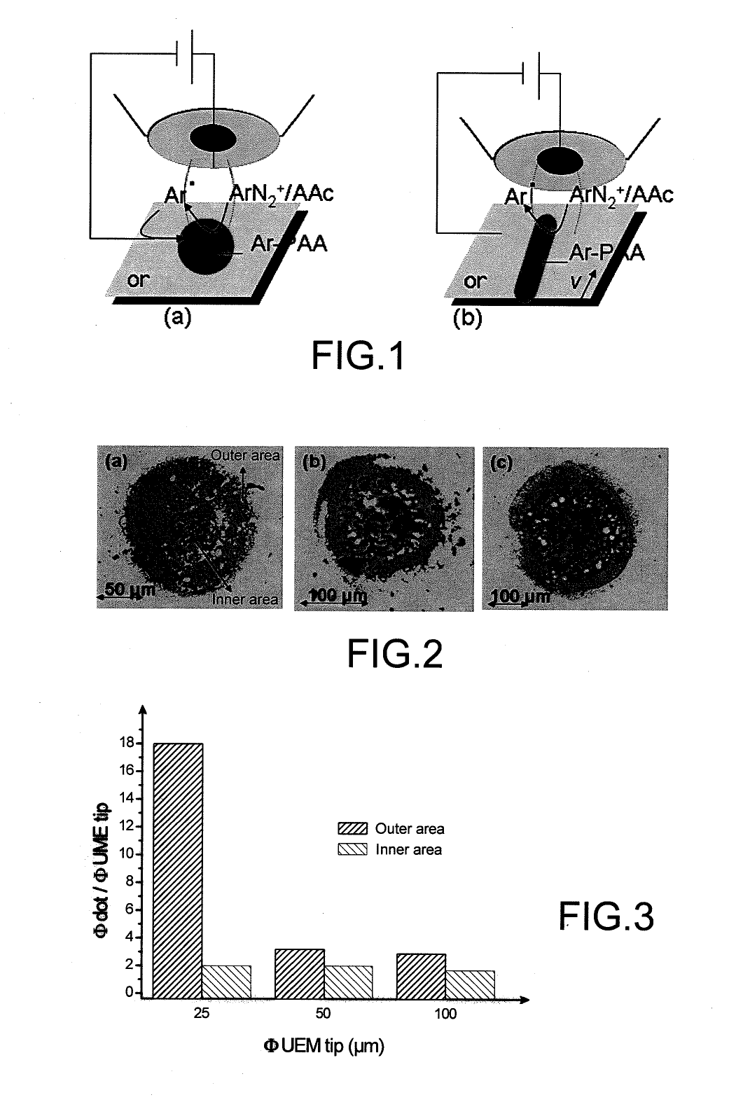

The electro-grafting was done using the chronoamperometric technique, continuous and pulsed, by applying a potential of −0.8 V in relation to the reference electrode used (Ag). The probe of the SECM was used in static mode to form dot patterns and in dynamic mode to form line patterns on the surface of the work electrode, as illustrated in FIG. 1. All of the samples were rinsed under ultrasounds with ethanol and water before analysis.

The grafted films were observed by optical microscopy (LEICA DMLM device with a CCD Leica DFC 320 camera) and analyzed by X-ray photoelectron spectrometry (XPS) (Kratos Axis Ultra DLD, Al Kα monochromatic source) and infrared spectrometry in reflection-absorption mode (Bruker IFS66 coupled to a HYPERION™ 3000 microscope). The polymer used here has spectroscopic characteristics that make it possible to follow its growth on the surface of the electrode.

I—Immobile Electrode

The pulsed chronoamperometry (4 pulses of 100 ms at −0.8 V each separated by a 10 ms interval) made it possible to locally form an electro-grafted polymer that is visible in optical microscopy regardless of the diameter of the ME used as shown in FIG. 2.

The form of the pattern that was grafted is homothetic to that of the ME. Two areas can be distinguished: an inner area and an outer area whereof the respective diameters correspond to about two and three times that of the ME.

The size of the outer area can be increased by decreasing the size of the ME as shown in FIG. 3. FIG. 3 shows the variation of the diameter of each of the areas as a function of that of the ME. The diameter of the inner area is about twice that of the ME, the diameter of the outer area increases greatly when one goes from the 100 μm ME to the 25 μm ME.

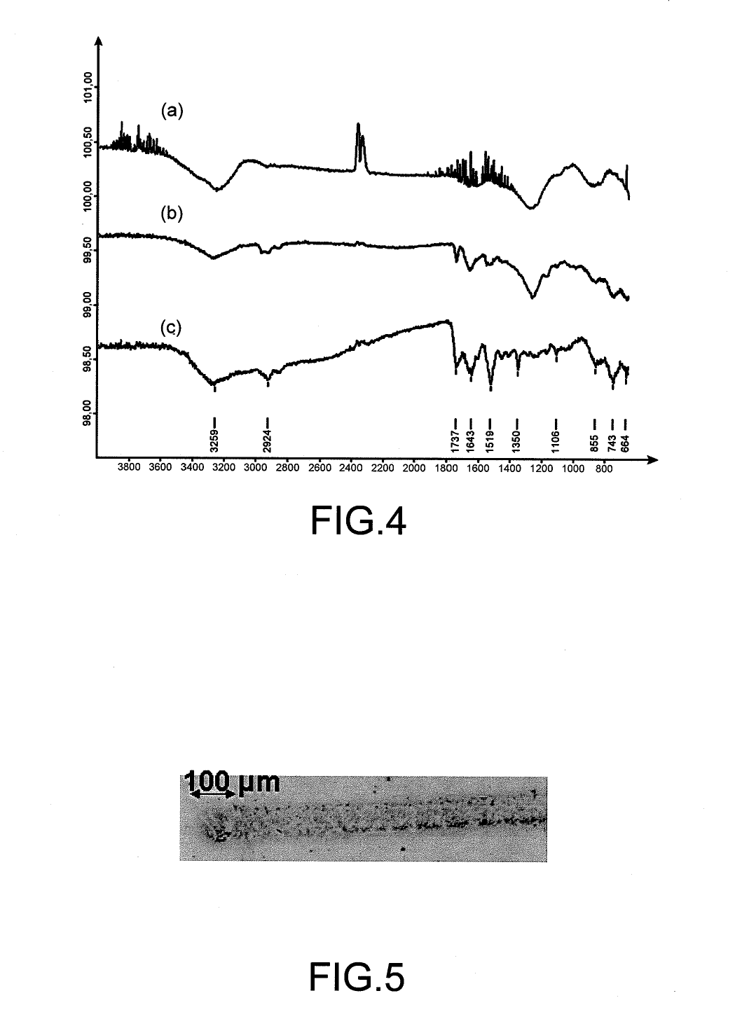

The presence of the characteristic bands of the polynitrophenylene (1530 and 1350 cm⁻¹ for NO₂ and 1600 cm⁻¹ for the phenyl group) and the polyacrylic acid (1730 cm⁻¹ for the carbonyl group), or PAA, during infrared measurements, confirms that the grafting of the PAA indeed took place as illustrated in FIG. 4.

The thickness of the film that was obtained, measured by AFM, is about 60 nm at the inner area and 110 nm for the outer area, the thickest area corresponding to the outer perimeter of the inner area. The transition between the inner area and the outer area is not linear and a “hollow” area exists between the two areas.

An XPS analysis was conducted (400×400 μm), for core levels of Au 4f, N 1s, O 1s, C 1s, on the grafted pattern using a ME with a diameter of 100 μm. It appeared that the film is essentially made up of polynitrophenylene on the periphery and that the polyacrylic acid is mostly present around the perimeter of the inner area. The analysis of the XPS profile made it possible to determine the existence of 6 distinct areas as a function of the intensity of each of the elements (Au, C, N et O). In areas (1) and (6), situated outside the main areas, gold is the predominant element. In areas (2) and (5), or between the inner area and the outer area, C, N and O are mostly present. In area 3, it appears that the organic coating is finer because the gold signal is greater. Lastly, in area (4), which corresponds to the hollow between the inner area and the outer area, the gold signal is again significant.

II—Electrode in Motion

In dynamic mode, the ME was moved over a distance of 2.2 mm at a constant height of 20 μm in relation to the surface of the sample at a speed of 50 μm·s⁻¹. The system was polarized at −0.8 V as before during the method.

The line of grafted film has an inner area about 80 μm wide and 110 μm for the outer area as illustrated in FIG. 5.

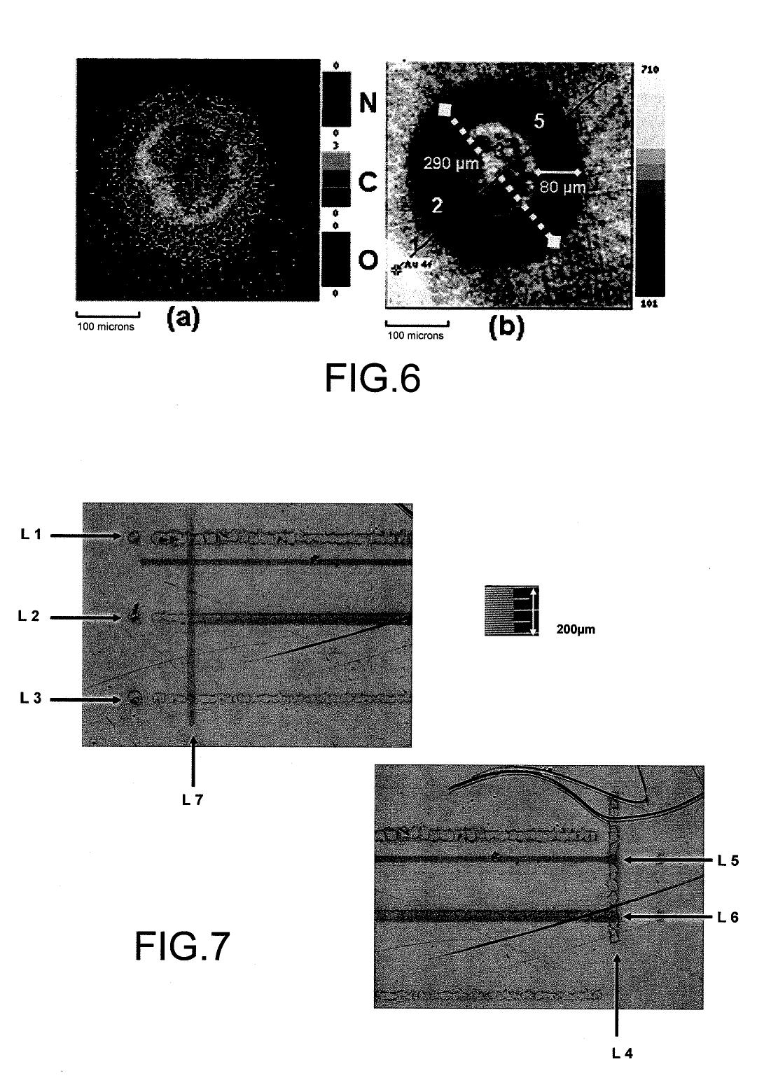

The same experiment was conducted by moving the ME at different heights, from d/a=0.2 to d/a=1.4, d representing the working distance and a the radius of the ME, as illustrated in FIG. 6. In FIGS. 6a and 6b, one can see that the variation of the height does not cause a significant change in the shape of the grafted films.

The same experiments were conducted successfully using an AFM having a probe, the ME, 100 nm wide, and led to grafted patterns 200 nm wide.

III—Multiple Films

On a same gold surface, different films were grafted using a ME with a diameter of 10 μm in motion and using a protocol similar to that previously described. The electrolytic solution previously mentioned was used as well as a solution in which 2-hydroxyethyl-methacrylate (HEMA) was substituted for the acrylic acid (AA). The image obtained by optical microscopy after the treatment is shown in FIG. 7, the following forms were applied to form the reference films L1 to L6 (speed of movement of the electrode, distance to the surface and monomer):

| | Speed | Distance | |
|---|---|---|---|
| Film | (μm/s) | (μm) | Monomer |
| L1 | 5 | 6 | HEMA |
| L2 | 50 | 6 | HEMA then AA |
| L3 | 100 | 6 | HEMA |
| L4 | 30 | 6 | HEMA |
| L5 | 50 | 10 | AA |
| L6 | 5 | 10 | AA then HEMA |
| L7 | 30 | 6 | AA |

For films L2 and L6, the ME was used twice in a row on the same course.

1-25. (canceled)

26. A method for preparing an organic film in a selected area of an electrically conducting or semiconducting substrate, comprising:
applying, in the presence of a liquid solution containing at least one organic adhesion primer and at least one radically polymerizable monomer and different from the organic adhesion primer, an electric potential to the substrate in the presence of a polarized microelectrode.

27. A method for preparing an organic film in a selected area of an electrically conducting or semiconducting substrate, comprising:
a) positioning a microelectrode near a surface of the selected area;
b) putting a liquid solution comprising at least one organic adhesion primer and at least one radically polymerizable monomer, different from said adhesion primer, in contact with at least said selected area; and
c) polarizing said microelectrode and a surface of said substrate, an electric potential of the surface being more cathodic than a reduction potential of the organic adhesion primer used in step (b),
wherein the steps (b) and (c) are performed in either order after the step (a).

28. The method according to claim 26, wherein said substrate has an inorganic surface.

29. The method according to claim 28, wherein said inorganic surface is formed by a material chosen among metals, noble metals, corroding metals, transition metals, metal alloys, and semiconducting materials.

30. The method according to claim 26, wherein said microelectrode is chosen from the group consisting of an ultramicroelectrode (UME), a probe of a scanning tunneling microscope (STM), a probe of a scanning electrochemical microscope (SECM), and a probe of an electrochemical atomic force microscope (el-AFM).

31. The method according to claim 27, wherein, during said step (a), said microelectrode is placed at a vertical portion of the surface of said selected area.

32. The method according to claim 26, wherein said organic adhesion primer is a cleavable aryl salt chosen from the group consisting of aryl diazonium salts, aryl ammonium salts, aryl phosphonium salts, aryl iodonium salts, and aryl sulfonium salts.

33. The method according to claim 26, wherein said organic adhesion primer is a compound of the following formula (I):
R—N₂⁺,A⁻ (I)
in which
A represents a monovalent anion, and
R represents an aryl group.

34. The method according to claim 32, wherein said aryl group is chosen from aromatic or heteroaromatic carbonaceous structures, mono- or polysubstituted, comprising one or several aromatic or heteroaromatic cycles each including 3 to 8 atoms, the heteroatom(s) being N, O, P or S, and substituent(s) containing one or several heteroatoms or C1 to C6 alkyl groups.

35. The method according to claim 33, wherein said aryl group is chosen from aromatic or heteroaromatic carbonaceous structures, mono- or polysubstituted, comprising one or several aromatic or heteroaromatic cycles each including 3 to 8 atoms, the heteroatom(s) being N, O, P or S, and substituent(s) containing one or several heteroatoms or C1 to C6 alkyl groups.

36. The method according to claim 33, wherein A is chosen among inorganic anions, halogenoborates, and organic anions.

37. The method according to claim 26, wherein said organic adhesion primer is chosen from the group consisting of phenyldiazonium tetrafluoroborate, 4-nitrophenyldiazonium tetrafluoroborate, 4-bromophenyldiazonium tetrafluoroborate, 4-aminophenyldiazonium chloride, 2-methyl-4-chlorophenyldiazonium chloride, 4-benzoylbenzenediazonium tetrafluoroborate, 4-cyanophenyldiazonium tetrafluoroborate, 4-carboxyphenyldiazonium tetrafluoroborate, 4-acetamidophenyldiazonium tetrafluoroborate, 4-phenylacetic diazonium acid tetrafluoroborate, 2-methyl-4-[(2-methylphenyl)diazenyl]benzenediazonium sulfate, 9,10-dioxo-9,10-dihydro-1-anthracenediazonium chloride, 4-nitronaphtalenediazonium tetrafluoroborate and naphtalenediazonium tetrafluoroborate.

38. The method according to claim 26, wherein said radically polymerizable monomer is a molecule including at least one ethylene-type bond.

39. The method according to claim 26, wherein said radically polymerizable monomer is a monomer of the following formula (II): 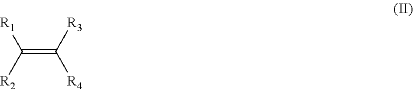
in which groups R₁ to R₄, identical or different, represent a non-metal monovalent atom such as a halogen atom, a hydrogen atom, a saturated or unsaturated chemical group, such as an alkyl group, an aryl group, a —COOR₅ or —OC(O)R₅ group in which R₅ represents a hydrogen atom or a C₁-C₁₂ alkyl group and preferably C₁-C₆, a nitrile, a carbonyl, an amine or an amide.

40. The method according to claim 26, wherein said radically polymerizable monomer is chosen from the group consisting of vinyl esters such as vinyl acetate, acrylic acid, acrylonitrile, methacrylonitrile, methyl methacrylate, ethyl methacrylate, butyl methacrylate, propyl methacrylate, hydroxyethyl methacrylate, hydroxypropyl methacrylate, glycidyle methacrylate and their derivatives; acrylamides and in particular aminoethyl, propyl, butyl, pentyl and hexyl methacrylamides, cyanoacrylates, diacrylates and dimethacrylates, tri-acrylates and tri-methacrylates, tetra-acrylates and tetra-methacrylates (such as pentaerythritol tetramethacrylate), styrene and its derivatives, parachloro-styrene, pentafluoro-styrene, N-vinyl pyrrolidone, 4-vinyl pyridine, 2-vinyl pyridine, vinyl, acryloyl or methacryloyle halides, di-vinylbenzene (DVB), and more generally vinyl or acrylate-, methacrylate-based cross-linking agents, and their derivatives.

41. The method according to claim 26, wherein said liquid solution also contains a solvent.

42. The method according to claim 41, wherein said solvent is a protic solvent chosen from the group consisting of water, acetic acid, hydroxylated solvents such as methanol and ethanol, liquid glycols with a low molecular weight such as ethyleneglycol, and mixtures thereof.

43. The method according to claim 26, wherein said liquid solution also contains at least one supporting electrolyte.

44. The method according to claim 26, wherein said liquid solution also contains at least one surface active agent.

45. The method according to claim 27, wherein said electric potential in step (c) is close to a reduction potential of the adhesion primer.

46. The method according to claim 27, wherein said electric potential in step (c) is up to 50% higher than the reduction potential of the adhesion primer.

47. The method according to claim 26, wherein said method includes an additional step of moving said microelectrode close to said selected area.

48. The method according to claim 26, wherein said method includes an additional step of functionalizing the prepared organic film.

49. The method according to claim 26, wherein said method is done in an electrolytic cell with three electrodes with a working electrode corresponding to the electrically conducting or semiconducting substrate, an auxiliary electrode corresponding to the microelectrode, and a reference electrode.

50. An insulating organic film grafted on a conducting or semiconducting substrate, prepared using a method as defined in claim 26,
wherein a thickness of said film has at least one inner area with a maximum height h(i) and an outer area with a maximum height h(e), with h(i)<h(e), separated by a hollow area with a maximum height h(c) with h(c)<h(i).

51. An insulating organic film grafted on a conducting or semiconducting substrate, prepared using a method as defined in claim 27,
wherein a thickness of said film has at least one inner area with a maximum height h(i) and an outer area with a maximum height h(e), with h(i)<h(e), separated by a hollow area with a maximum height h(c) with h(c)<h(i).

52. The method according to claim 27, wherein said substrate has an inorganic surface.

53. The method according to claim 52, wherein said inorganic surface is formed by a material chosen among metals, noble metals, corroding metals, transition metals, metal alloys, and semiconducting materials.

54. The method according to claim 27, wherein said microelectrode is chosen from the group consisting of an ultramicroelectrode (UME), a probe of a scanning tunneling microscope (STM), a probe of a scanning electrochemical microscope (SECM), and a probe of an electrochemical atomic force microscope (el-AFM).

55. The method according to claim 27, wherein said organic adhesion primer is a cleavable aryl salt chosen from the group consisting of aryl diazonium salts, aryl ammonium salts, aryl phosphonium salts, aryl iodonium salts, and aryl sulfonium salts.

56. The method according to claim 27, wherein said organic adhesion primer is a compound of the following formula (I):
R—N₂⁺,A⁻ (I)
in which
A represents a monovalent anion, and
R represents an aryl group.

57. The method according to claim 55, wherein said aryl group is chosen from aromatic or heteroaromatic carbonaceous structures, mono- or polysubstituted, comprising one or several aromatic or heteroaromatic cycles each including 3 to 8 atoms, the heteroatom(s) being N, O, P or S, and substituent(s) containing one or several heteroatoms or C1 to C6 alkyl groups.

58. The method according to claim 56, wherein said aryl group is chosen from aromatic or heteroaromatic carbonaceous structures, mono- or polysubstituted, comprising one or several aromatic or heteroaromatic cycles each including 3 to 8 atoms, the heteroatom(s) being N, O, P or S, and substituent(s) containing one or several heteroatoms or C1 to C6 alkyl groups.

59. The method according to claim 56, wherein A is chosen among inorganic anions, halogenoborates, and organic anions.

60. The method according to claim 27, wherein said organic adhesion primer is chosen from the group consisting of phenyldiazonium tetrafluoroborate, 4-nitrophenyldiazonium tetrafluoroborate, 4-bromophenyldiazonium tetrafluoroborate, 4-aminophenyldiazonium chloride, 2-methyl-4-chlorophenyldiazonium chloride, 4-benzoylbenzenediazonium tetrafluoroborate, 4-cyanophenyldiazonium tetrafluoroborate, 4-carboxyphenyldiazonium tetrafluoroborate, 4-acetamidophenyldiazonium tetrafluoroborate, 4-phenylacetic diazonium acid tetrafluoroborate, 2-methyl-4-[(2-methylphenyl)diazenyl]benzenediazonium sulfate, 9,10-dioxo-9,10-dihydro-1-anthracenediazonium chloride, 4-nitronaphtalenediazonium tetrafluoroborate and naphtalenediazonium tetrafluoroborate.

61. The method according to claim 27, wherein said radically polymerizable monomer is a molecule including at least one ethylene-type bond.

62. The method according to claim 27, wherein said radically polymerizable monomer is a monomer of the following formula (II): 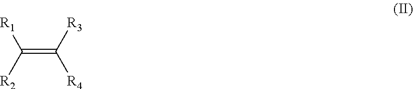
in which groups R₁ to R₄, identical or different, represent a non-metal monovalent atom such as a halogen atom, a hydrogen atom, a saturated or unsaturated chemical group, such as an alkyl group, an aryl group, a —COOR₅ or —OC(O)R₅ group in which R₅ represents a hydrogen atom or a C₁-C₁₂ alkyl group and preferably C₁-C₆, a nitrile, a carbonyl, an amine or an amide.

63. The method according to claim 27, wherein said radically polymerizable monomer is chosen from the group consisting of vinyl esters such as vinyl acetate, acrylic acid, acrylonitrile, methacrylonitrile, methyl methacrylate, ethyl methacrylate, butyl methacrylate, propyl methacrylate, hydroxyethyl methacrylate, hydroxypropyl methacrylate, glycidyle methacrylate and their derivatives; acrylamides and in particular aminoethyl, propyl, butyl, pentyl and hexyl methacrylamides, cyanoacrylates, diacrylates and dimethacrylates, tri-acrylates and tri-methacrylates, tetra-acrylates and tetra-methacrylates (such as pentaerythritol tetramethacrylate), styrene and its derivatives, parachloro-styrene, pentafluoro-styrene, N-vinyl pyrrolidone, 4-vinyl pyridine, 2-vinyl pyridine, vinyl, acryloyl or methacryloyle halides, di-vinylbenzene (DVB), and more generally vinyl or acrylate-, methacrylate-based cross-linking agents, and their derivatives.

64. The method according to claim 27, wherein said liquid solution also contains a solvent.

65. The method according to claim 64, wherein said solvent is a protic solvent chosen from the group consisting of water, acetic acid, hydroxylated solvents such as methanol and ethanol, liquid glycols with a low molecular weight such as ethyleneglycol, and mixtures thereof.

66. The method according to claim 27, wherein said liquid solution also contains at least one supporting electrolyte.

67. The method according to claim 27, wherein said liquid solution also contains at least one surface active agent.

68. The method according to claim 27, wherein said method includes an additional step of moving said microelectrode close to said selected area.

69. The method according to claim 27, wherein said method includes an additional step of functionalizing the prepared organic film.

70. The method according to claim 27, wherein said method is done in an electrolytic cell with three electrodes with a working electrode corresponding to the electrically conducting or semiconducting substrate, an auxiliary electrode corresponding to the microelectrode, and a reference electrode.
